(19) United States
(12) Patent Application Publication
(10) Pub. No.: US 2025/0087466 A1
(43) Pub. Date: Mar. 13, 2025

(54) PROCESSING APPARATUS AND PROCESSING METHOD

(71) Applicant: United Semiconductor (Xiamen) Co., Ltd., Xiamen (CN)

(72) Inventors: Ching-Shu Lo, Singapore (SG); Yan Cai, Singapore (SG); Tsung Che Lin, Singapore (SG); Wen Yi Tan, Xiamen (CN)

(73) Assignee: United Semiconductor (Xiamen) Co., Ltd., Xiamen (CN)

(21) Appl. No.: 18/381,647

(22) Filed: Oct. 19, 2023

(30) Foreign Application Priority Data
Sep. 12, 2023 (CN) 202311171034.2

(51) Int. Cl. H01J 37/32; H01L 21/683

(52) U.S. Cl. CPC H01J 37/32715; H01J 37/32834; H01L 21/6833; H01J 2237/334

(57) ABSTRACT

The present disclosure relates to a processing apparatus and a processing method, and the processing apparatus includes a chamber, a wafer carrier, at least one air inlet and at least one electrode, wherein the wafer carrier is extended into the chamber, the gas inlet is arranged around the chamber, and the electrode is disposed on the chamber.

### BACKGROUND OF THE INVENTION

### 1. Field of the Invention

The present disclosure relates generally to a process apparatus and a processing method, and more particularly to a process apparatus and a processing method for semiconductor device.

### 2. Description of the Prior Art

As is well known, integrated circuits (ICs) have developed to integrate millions of components including transistors, capacitor, and resistor are fabricated on a single semiconductor chip. The fabrication of these components refers to various operating stages, in which, an etching process is carried out by depositing a material layer on a surface of a substrate, followed by etching the material layer through a plasma to form corresponding devices or patterns on the substrate. However, as the size of integrated circuits continues to shrink, a faster wiring and a higher integration of circuit are further requested for chip design. Under this requirement, the uniformity and the processing quality of the etching process become more important, thus that, there is a crucial need for improving the processing apparatus and the process method in the related arts, for achieving better etching efficiency and quality under the demand of miniaturizing integrated circuits.

### SUMMARY OF THE INVENTION

An object of the present disclosure is to provide a process apparatus and a processing method, in which a wafer is arranged in a reverse direction, with the wafer surface facing the bottom surface of a chamber, and with the etching plasma being generated between the wafer carrier and the bottom surface of the chamber, so as to prevent the impurity in the environment from falling on the wafer surface due to the gravity during the etching process, and also to prevent the by-products from settling on the wafer surface with etching gas. Accordingly, the processing apparatus and the processing method of the present disclosure enables to effectively enhance the performance of the etching process, to improve the pattern defects or structural defects of the wafer, to achieve a better processing quality.

To achieve the above object, the present disclosure provides a processing apparatus including a chamber, a wafer carrier, at least one gas inlet, and at least one electrode. The wafer carrier is extended into the chamber. The at least one gas inlet is disposed around the chamber. The at least one electrode is disposed on the chamber.

To achieve the above object, the present disclosure provides a processing method including following steps. Firstly, a wafer is provided into a chamber, and an etching gas is injected into the chamber from a periphery of the wafer. Then, the wafer is etched through the etching gas.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a processing apparatus according to a first embodiment of the present disclosure.

FIG. 2 is a schematic diagram illustrating a processing apparatus according to a second embodiment of the present disclosure.

FIG. 3 to FIG. 6 are schematic diagrams illustrating a processing method according to a preferable embodiment of the present disclosure, in which:

FIG. 3 illustrating a process flow of the processing method;

FIG. 4 illustrating a cross-sectional view of a process apparatus after carrying a wafer;

FIG. 5 illustrating a cross-sectional view of a process apparatus after reversing the wafer; and

FIG. 6 illustrating a cross-sectional view of a process apparatus after generating etching plasma.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

Please refer to FIG. 1, which illustrates a process apparatus 10 according to a first embodiment of the present disclosure. As shown in FIG. 1, the process apparatus 10 includes a chamber 100, a wafer carrier 110 and at least one gas inlet 112. The chamber 100 for example includes a vacuum chamber, preferably an etching chamber such as a plasma etching chamber, a plasma processing chamber or the like, but not limited thereto. The wafer carrier 110 and the gas inlet 112 are both disposed in the chamber 100. The wafer carrier 110 is extended in the chamber 100, and which includes a carrier for carrying wafers, and preferably includes an electrostatic chuck (ESC) for absorbing wafers through an electrical force. The gas inlet 112 is arranged at the top of the chamber 100, with a required etching gas 112a being introduced into the chamber 100 via the gas inlet 112. In one embodiment, a plurality of gas inlets 112 are simultaneously arranged at the top of the chamber 100, to deliver the etching gas 112a to every portion inside the chamber 100 in an uniformly manner.

The process apparatus 10 further includes at least one electrode 114, such as a bottom electrode, with one end of the electrode 114 being connected to the chamber 100, and with another end of the electrode 114 being connected to the ground. Accordingly, the gas disaggregation is conducted due to the electrode 114 underneath, to carry out a required process like etching process to a wafer 122 on the wafer carrier 110, but not limited thereto. In another embodiment, the process apparatus 10 may optionally include two electrodes 114, 116 as shown in FIG. 1, serving as a top electrode and a bottom electrode respectively, but is not limited thereto. On the other hand, the process apparatus 10 further includes an air valve 118 and a pump 120 both disposed below the chamber 100. The air valve 118 is configured as a gas regulator, and the pump 120 is arranged below the air valve 118 for exhausting the gas from the chamber 100. For example, when an inner pressure of the chamber 100 reaches to a certain limit, and pump 120 is turn on to exhaust the gas from the chamber. In this way, the pressure condition inside the chamber 100 may be maintain at a certain value to facilitate the processing of the required process such as etching process.

With these arrangements, the process apparatus 10 of the present embodiment enables to effectively carry out the etching process on the wafer 122. Firstly, the wafer 122 is provided on the wafer carrier 110, and the wafer is electro-chucking on a plane 110a of the wafer carrier 110, with a surface of the wafer 122 facing to the top of the chamber 100. Then, the required etching gas 112a will be introduced into the chamber 100 via the gas inlets 122 at the top, conducting the gas disaggregation through the electrodes 114, 116, followed by generating etching plasma 128 and carrying out the etching process on the surface of the wafer 122. It is noted that, in the present embodiment, the etching plasma 128 is generated between the wafer carrier 110 and the gas inlet 112 in a vertical direction of the process apparatus 10, with the surface of the wafer 122 facing to the etching plasma 128 and the top of the chamber 100, as shown in FIG. 1. On the other hand, an etching frequency may be optionally adjusted any time through the electrodes 114, 116, but not limited thereto.

One of ordinary skill in the arts would easily realize the processing apparatus in the present disclosure is not limited to the aforementioned embodiment, and may further include other examples or variations, so as to meet the practical requirements. For example, various impurities 124 and/or etching by-products 126 may be generated in the chamber 100 during the etching process, and the impurities 124 may fall on the surface of the wafer 122 via the gravity, and also, the by-products 126 may be deposited on the surface of the wafer 122 with the etching plasma 128. Accordingly, the impurities 124 falling on the surface may lead to structural defects or pattern defects on the wafer 122, and the depositing by-products 126 may seriously affect the device performance and the operation of the wafer 122.

According to another embodiment of the present disclosure, another processing apparatus is provided to prevent the impurities 124 and/or the by-products 126 from affecting the etching process, thereby sufficiently improving the possible structural defects and the pattern defects, and improving the device performance and the operation. The following description will detail the different embodiments of the processing apparatus. To simplify the description, the following description will detail the dissimilarities among the different embodiments and the identical features will not be redundantly described. In order to compare the differences between the embodiments easily, the identical components in each of the following embodiments are marked with identical symbols.

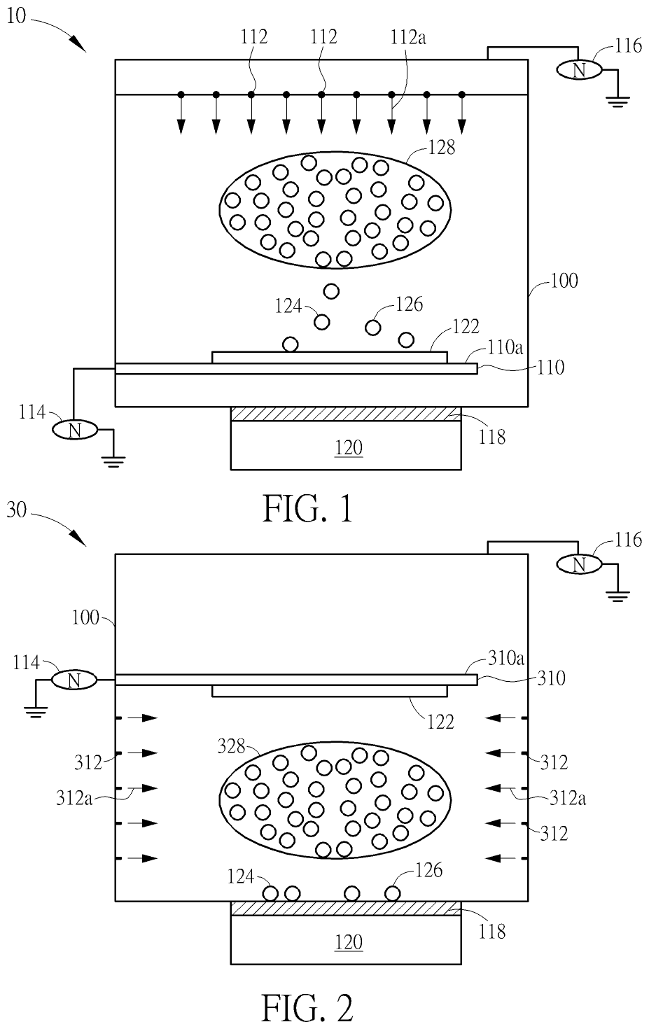

Please refer to FIG. 2, which illustrate a processing apparatus 30 according to a second embodiment of the present disclosure. The structure of the processing apparatus 30 in the present embodiment is substantially similar to that of the processing apparatus 10 in the aforementioned embodiment, and all the similarities will not be redundantly described hereinafter. The difference between the present embodiment and the aforementioned embodiment is mainly in that a wafer carrier 310 of the processing apparatus 30 includes a reversible plane 310a capable of flipping chip.

As shown in FIG. 2, the processing apparatus 30 includes the chamber 100, the wafer carrier 310, at least one gas inlet 312 and at least one electrode 114. The wafer carrier 310 and the gas inlet 312 are both disposed in the chamber 100, and the wafer carrier 310 is also extended in the chamber 100. In one embodiment, the wafer carrier 310 for example includes a carrier for carrying wafers, and preferably includes an electrostatic chuck for absorbing wafers through an electrical force, but not limited thereto.

It is noted that, the gas inlet 312 of the present embodiment is disposed around the chamber 100, to deliver the etching gas 312a into the chamber 100 in a uniform manner, and the lateral entering route of the etching gas 312a can prevent the impurities 124 or the by-products 126 in the chamber 100 from directly falling on the surface of the wafer 122, thereby dramatically enhancing the function and the quality of the etching process, and also improving the possible pattern defects or structural defects on the wafer 122. In one embodiment, the processing apparatus 30 for example includes a plurality of the gas inlet 312 respectively arranged on a peripheral sidewall inside the chamber 100, and preferably on the peripheral sidewall around the wafer carrier 310 as shown in FIG. 2, but not limited thereto. Accordingly, the entering route of the etching gas 312a through the gas inlet 312 of the present embodiment is capable of preventing the impurities 124 or the by-products 126 from directly falling on the surface of the wafer 122, thereby avoiding the pattern defects or structural defects on the wafer 122 and improving the device performance and the operation.

It is also noted that, the wafer carrier 310 further includes the reversible plane 310a that can be selectively flipped to face the top surface or the bottom surface of the chamber 100. Precisely speaking, while the wafer 122 is carried by the wafer carrier 310, the reversible plane 310a is faced the top surface of the chamber 100 at first, and next, the reversible plane 310a is flipped to face the bottom surface of the chamber 100, with the surface of the wafer 122 disposed on the reversible plane 310a also face to the bottom surface of the chamber 100, as shown in FIG. 2. In addition, the processing apparatus 30 further includes the air valve 118 and the pump 120 disposed below the chamber 100, wherein all of the functions and the detailed features of the air valve 118 and the pump 120, and the aforementioned chamber 100 and the electrodes 114, 116 are substantially similar to those in the aforementioned first embodiment, and will not be redundantly described hereinafter.

With these arrangements, the process apparatus 30 of the present embodiment also enables to effectively carry out the etching process on the wafer 122, with the etching process being performed on the surface of the wafer 122 without the contamination of the impurities 124 and the by-products 126. According to the processing apparatus 30 of the present embodiment, the required etching gas 312a is introduced to the chamber 100 from the gas inlet 312, followed by inducing the gas disaggregation of the etching gas 312a through the electrodes 114, 116, and generating the etching plasma 328 to carry out the etching process on the surface of the wafer 122. In one embodiment, the processing apparatus 30 may additionally include a containment rings (not shown in the drawing) between the wafer carrier 310 and the bottom surface of the chamber 100 to confined the etching plasma 328 driving toward the surface of the wafer 122 via an electric field or a magnetic field, thereby facilitating the performance of the etching process.

It is noted that, the gas inlets 312 of the present embodiment is arranged around the chamber 100. Although the impurities 124 or the by-products 126 inside the chamber 100 will still fall on the bottom surface of the chamber 100 by the gravity, the lateral entering route of the etching gas 312a can prevent the impurities 124 or the by-products 126 from directly falling on the surface of the wafer 122, without contaminating the wafer 122. Furthermore, since the wafer 122 is arranged on the revisable plane 310a, with the surface of the wafer 122 being flipped to face the bottom surface of the chamber 100, the etching plasma 328 generated thereby is located between the wafer carrier 310 and the bottom surface of the chamber 100 along a vertical direction of the processing apparatus 30, right below the wafer 122 and the wafer carrier 310, which is beneficial on etching the surface of the wafer 122, as shown in FIG. 2. In this way, while etching the surface of the wafer 122 through the etching process, the impurities 124 and the by-products 126 falling on the bottom of the chamber 100 are also pumped out of the chamber with the exhausted gas via the air valve 118 and the pump 120. That is, the processing apparatus 30 of the present embodiment is capable of avoiding possible defects caused by the impurities 124 and/or the by-products 126, thereby significantly improving the performance and operation of the wafer 122.

In order to make people skilled in the art of the present disclosure easily understand the semiconductor device 30 of the present disclosure, the processing method of the processing apparatus 30 in the present disclosure will be further described below.

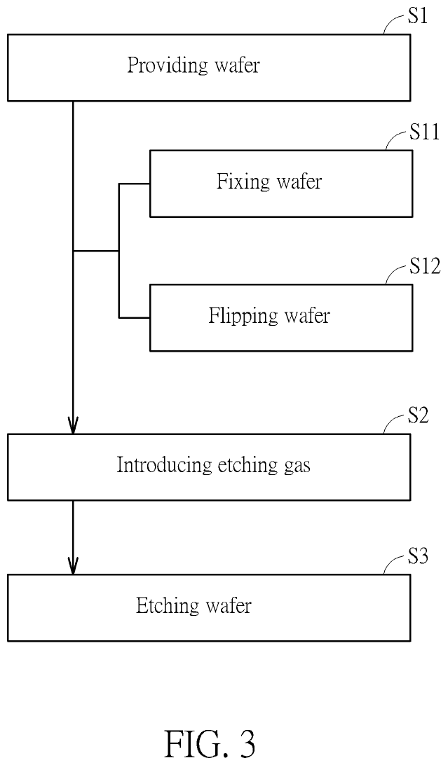

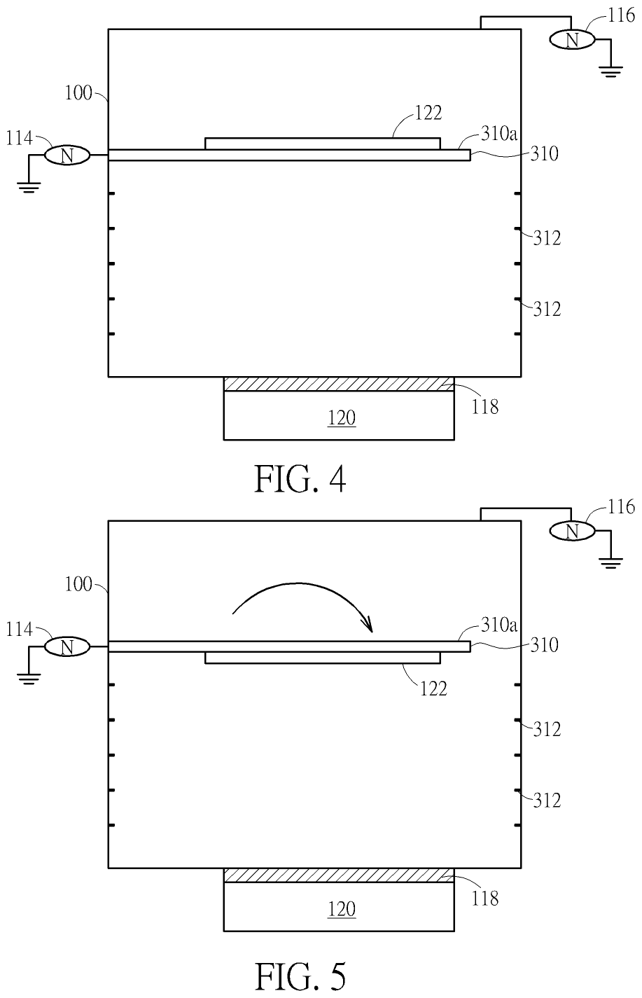

Please refer to FIG. 3 to FIG. 6, which illustrate a processing method according to a preferable embodiment of the present disclosure, and include but not limited to the following steps. Firstly, a step S1 of providing wafer is carried out. As shown in FIG. 3 and FIG. 4, a wafer 122 is provided into a chamber 100, wherein a plurality of gas inlets 312 is disposed around the chamber 100, and two electrodes 114, 116 are disposed on the chamber 100, and an air valve and a pump 120 are disposed below the chamber 100. In one embodiment, the chamber 100 for example includes a vacuum chamber, preferably an etching chamber such as a plasma etching chamber, a plasma processing chamber or the like, but not limited thereto.

Then, a step S11 of fixing wafer is carried out. It is noted that, while the wafer 122 is transferred into the chamber 100 at first, the wafer 122 is disposed on a wafer carrier 310, with the wafer 122 being fixed on a revisable plane 310a of the wafer carrier 310. In embodiment, the wafer 122 is a preferably for example electro-chucking on the revisable plane 310a, but is not limited thereto. With these arrangements, a surface of the wafer 122 may face to a top surface of the chamber 100, as shown in FIG. 4. In another embodiment, the wafer 122 may also be fixed on the wafer carrier 310 before transferring the wafer 122 into the chamber 100, and the wafer carrier 310 is then extended into the chamber to transfer the wafer 122 into the chamber 100.

Next, a step S12 of flipping wafer is carried out. As shown in FIG. 3 and FIG. 5, the wafer 122 is flipped to face a bottom surface of the chamber 100 by flipping the revisable plane 310a, after being fixed on the revisable plane 310a. Accordingly, the gas inlets 312 arranged around the inner side of the chamber 100 may be located below the surface of the wafer 122, between the wafer carrier 310 and the bottom surface of the chamber 100, as shown in FIG. 5. In another embodiment, the wafer 122 may be optionally fixed on the wafer carrier 310 and flipped to a reverse direction by the wafer carrier 310 at first, and the wafer carrier 310 is then transferred into the chamber 100. In this way, the wafer 122 will directly face the bottom surface of the chamber 100 while transferring into the chamber 100.

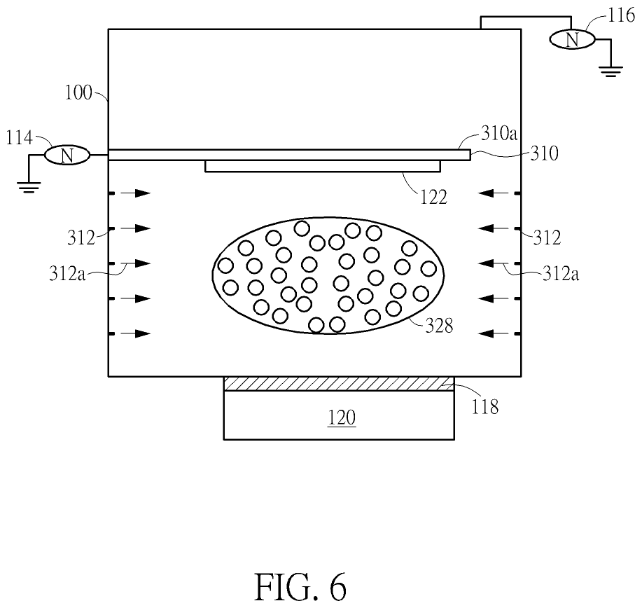

After that, a step S2 of introducing etching gas is carried out. As shown in FIG. 3 and FIG. 6, an etching gas 312a is introduced from the gas inlets 312 around the chamber 100, with the etching gas 312a introduced from the lateral side being transformed into ions or active gas by the electrodes 114, 116, thereby generating etching plasma 328. It is noted that, since the etching gas 312a is introduced in the chamber 100 to around the wafer 122, the impurities (not shown in FIG. 3 to FIG. 6) and/or the by-products (not shown in FIG. 3 to FIG. 6) inside the chamber 100 will directly fall on the bottom surface of the chamber 100 instead of falling on the wafer 122 by the gravity, which is beneficial on improving the possible defects of the wafer 122. Also, the lateral entering route of the etching gas 312a will confine the etching plasma 328 between the wafer 122 (the wafer carrier 310) and the bottom surface of the chamber 100, thereby improving the etching quality.

Following these, as shown in FIG. 3 and FIG. 6, a step S3 of etching wafer is carried out. Precisely speaking, the etching process of the wafer 122 is performed by firstly generating the etching plasma 328 through the etching gas 312, so that, the surface of the wafer 122 is processed with the etching plasma 328, following by forming a required pattern or a required structure thereon. It is noted that, while performing the etching process of the wafer 122, the surface of the wafer 122 still faces the bottom surface of the chamber 100, as well as the etching plasma 328 between the wafer carrier 310 and the bottom surface of the chamber 100, thus that facilitating the performance of etching the surface of the wafer 122.

In one embodiment, while performing the etching process, a gas adjustment process (not shown in the drawings) may be optionally carried out by adjusting the etching frequency of the etching gas 312a via the electrodes 114, 116. Also, after performing the etching process, a gas exhausting process (not shown in the drawings) may also be carried out by exhausting the etching gas 312a in the chamber 100 from the air valve 118 and the pump 120 below the chamber 100. Meanwhile, the impurities and/or the by-products inside the chamber 100 directly falling on the bottom surface of the chamber 100 will also be pumped out the chamber 100, as the etching gas 312a is exhausted from the chamber 100, so as to prevent from the possible contamination and defects caused by the impurities and/or the by-products.

Through these arrangements, the etching gas is introduced to around the wafer thus that, the impurities and/or the by-products inside the chamber 100 will not directly fall on the wafer. In addition, the wafer carrier is flipped to face the bottom surface of the chamber before the etching process, and the wafer surface is also face the bottom surface of the chamber thereby. In this way, the lateral entering route of the etching gas 312a will confine the etching plasma between the wafer and the bottom surface of the chamber, so as to facilitate the performance of the etching process. With these arrangements, the processing method of the present embodiment is also capable of preventing the impurities and/or the by-products from affecting the etching process of the wafer, so that, the possible defects of the wafer caused by the impurities and/or the by-products may be dramatically improved, and the etching function and the quality may be greatly enhanced, thereby achieving better wafer function and operation.

Overall speaking, the present disclosure provides a processing apparatus and a processing method, in which a wafer is arranged in a reverse direction to make the wafer surface facing the bottom surface of a chamber, and to confine the etching plasma being between the wafer carrier and the bottom surface of the chamber, so as to prevent the impurity in the environment from falling on the wafer surface due to the gravity during the etching process, and also to prevent the by-products from settling on the wafer surface with etching gas. Accordingly, the processing apparatus and the processing method of the present disclosure enables to effectively enhance the performance of the etching process, to improve the pattern defects or the structural defects of the wafer, and also to achieve a better processing quality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A processing apparatus, comprising:
a chamber;
a wafer carrier, extended into the chamber;
at least one gas inlet, disposed around the chamber; and
at least one electrode disposed on the chamber.

2. The processing apparatus according to claim 1, wherein the gas inlet is disposed on a sidewall below the wafer carrier.

3. The processing apparatus according to claim 1, wherein the chamber further comprises etching plasma between the wafer carrier and a bottom surface of the chamber.

4. The processing apparatus according to claim 3, wherein the wafer carrier further comprises a reversible plane.

5. The processing apparatus according to claim 4, wherein the reversible plane faces to the bottom surface of the chamber.

6. The processing apparatus according to claim 4, wherein the reversible plane comprises an electrostatic chuck.

7. The processing apparatus according to claim 1, further comprising an air valve disposed below the chamber.

8. The processing apparatus according to claim 7, further comprising a pump disposed under the air valve.

9. A processing method, comprising:
providing a wafer into a chamber;
introducing an etching gas into the chamber from a periphery of the wafer; and
etching the wafer through the etching gas.

10. The processing method according to claim 9, before introducing the etching gas, further comprising:
flipping the wafer to face a bottom surface of the chamber.

11. The processing method according to claim 10, further comprising:
generating etching plasma within the chamber, between the bottom surface of the chamber and the wafer.

12. The processing method according to claim 10, further comprising:
transferring the wafer into the chamber;
disposing the wafer on a wafer carrier within the chamber, wherein the wafer carrier faces a top surface of the chamber; and
flipping the wafer carrier to face the bottom surface of the chamber.

13. The processing method according to claim 12, further comprising:
electro-chucking the wafer on the wafer carrier, before flipping the wafer carrier.

14. The processing method according to claim 9, further comprising:
exhausting the etching gas from a bottom surface of the chamber.

15. The processing method according to claim 14, further comprising:
exhausting impurities and bi-products while exhausting the etching gas from the bottom surface of the chamber.

16. The processing method according to claim 9, further comprising:
adjusting an etching frequency through at least one electrode disposed on the chamber.
